(19) United States
(12) Patent Application Publication
(10) Pub. No.: US 2025/0251464 A1
(43) Pub. Date: Aug. 7, 2025

(54) EQUIPMENT DIAGNOSIS DEVICE AND EQUIPMENT DIAGNOSIS SYSTEM

(71) Applicant: Mitsubishi Electric Corporation, Tokyo (JP)

(72) Inventors: Yoshimasa WATANABE, Tokyo (JP); Yasuyuki OKADA, Tokyo (JP); Jin INOUE, Tokyo (JP)

(73) Assignee: Mitsubishi Electric Corporation, Tokyo (JP)

(21) Appl. No.: 18/844,111

(22) PCT Filed: Nov. 11, 2022
(86) PCT No.: PCT/JP2022/042020

§ 371 Date: Apr. 16, 2025

(30) Foreign Application Priority Data
Mar. 17, 2022 (JP) 2022-042713

(51) Int. Cl. G01R 31/52; G01R 29/26

(52) U.S. Cl. CPC G01R 31/52; G01R 29/26

(57) ABSTRACT

An equipment diagnosis device (100) includes a leakage current sensor (10), an equipment condition acquisition unit (20) to acquire equipment condition as at least either condition of a load equipment (1) or surrounding environment of the load equipment (1), an operation mode determination unit (36) to determine an operation mode of the leakage current sensor (10) at an operation mode for leakage detection in normal times or an operation mode for abnormality diagnosis based on a condition signal outputted from the equipment condition acquisition unit (20), a leakage current sensor drive unit (31), and a diagnosis unit (37) that makes a diagnosis on the load equipment (1) based on a detection signal outputted from the leakage current sensor (10) and the condition signal outputted from the equipment condition acquisition unit (20). When the equipment condition satisfies a switching condition, the operation mode determination unit (36) switches the operation mode of the leakage current sensor (10) to the operation mode for abnormality diagnosis.

### TECHNICAL FIELD

The present disclosure relates to an equipment diagnosis device and an equipment diagnosis system.

### BACKGROUND ART

Load equipment (e.g., motor or the like) driven by electric power supplied from a power supply has become widespread. As the load equipment is used for a long period, there occur insulation deterioration due to aging of insulating members, failure and damaging of components, and so forth.

If a leak current (hereinafter referred to also as a “leakage”) flows into a part where the insulation deterioration has occurred, that can cause an electric shock to a human body or activation of a leakage current sensor (e.g., a ground-fault interrupter or an earth leakage relay) provided between the power supply and the load equipment. In this case, for an emergency inspection or security, it is necessary to stop the supply of the electric power to the load equipment and identify the cause and the position of the occurrence of the leakage. Further, when a failure or damage of a component has occurred, it takes a considerable amount of time also for urgent work (specifically, arrangement of a replacement component, component replacement work, etc.). Therefore, sophistication of a load equipment diagnosis device is being requested.

In general, a zero-phase current transformer (ZCT) installed in the ground-fault interrupter or the earth leakage relay is used for measuring the leak current due to the insulation deterioration. Further, there has been known a system that executes insulation monitoring based on voltage information and leakage information in regard to an electric path connecting the power supply and the load equipment (see Patent Reference 1, for example).

A leakage current sensor equipped with the zero-phase current transformer is a sensor of the so-called passive type, for example, and measures the leakage based on a load resistance connected to both ends of a coil wound around a magnetic core. Further, in recent years, a sensor of the active type, employing the flux gate method of detecting a change in the magnetic field, is also used as the leakage current sensor (see Patent Reference 2, for example).

Furthermore, in order to detect the insulation deterioration in an electric power facility, there has been proposed a configuration that increases diagnostic accuracy based on signals outputted from a plurality of sensors of different types (see Patent Reference 3, for example). Moreover, there has also been known a device that detects deterioration of the load equipment and determines the presence or absence of a failure or damage of a component based on the frequency spectrum of electric current detected by a current sensor (see Patent References 4 and 5, for example). In addition, there has also been known a device that determines the presence or absence of a failure or damage in a component of the load equipment based on the result of sensing by a vibration sensor installed in the load equipment (see Patent Reference 6, for example).

### PRIOR ART REFERENCE

### Patent Reference

Patent Reference 1: Japanese Patent Application Publication No. 2019-109192 (see FIG. 1)
Patent Reference 2: Japanese Patent Application Publication No. 2013-539538 (see FIG. 2)
Patent Reference 3: Japanese Patent Application Publication No. 2019-135455 (see FIG. 5)
Patent Reference 4: International Publication No. WO 2018/087885 (see FIG. 1)
Patent Reference 5: Japanese Patent Application Publication No. 2017-181437 (see FIG. 4)
Patent Reference 6: Japanese Patent Application Publication No. 2021-144054 (see FIG. 1)

### SUMMARY OF THE INVENTION

### Problem to be Solved by the Invention

Importance of sensor fusion technology is increasing since it is not easy to measure or make judgments on various properties, such as the insulation deterioration of the load equipment and a failure or damage of a component of the load equipment, by using only one sensor. While detection sensitivity of the leakage current sensor varies depending on the purpose and use of the insulation monitoring, the detection sensitivity is generally a fixed value. Therefore, it is difficult to make a diagnosis on various events including the insulation monitoring by using only one leakage current sensor. Although it is also possible to consider a method of changing the detection sensitivity by adjusting the gain of a booster amplifier provided after the ground-fault interrupter, it is difficult to change the detection sensitivity in a normal operation condition. Further, a method of feeding a test current to the leakage current sensor as described in the Patent Reference 1 is also difficult since it becomes necessary to frequently change the detection sensitivity in a normal operation condition.

Furthermore, when a plurality of leakage current sensors differing in the detection sensitivity are arranged in the device as described in the Patent Reference 3, the cost rises. Moreover, the cost rises also when correlation between abnormality of the load equipment and output signals of the leakage current sensors is unknown yet, since the number of leakage current sensors needs to be increased. In addition, the cost rises also when a database of the correlation is constructed.

An object of the present disclosure, which has been made to resolve the above-described problems, is to provide an equipment diagnosis device and an equipment diagnosis system that realize a low cost, easy diagnosis on the load equipment, and high reliability of the diagnosis.

### Means for Solving the Problem

An equipment diagnosis device according to an aspect of the present disclosure is an equipment diagnosis device to make a diagnosis on load equipment driven by electric power supplied from a power supply unit through an electric circuit. The equipment diagnosis device includes a leakage current sensor to output a detection signal in a waveform corresponding to electric current leaking out from the electric circuit, an equipment condition acquisition unit to acquire equipment condition as at least either condition of the load equipment or surrounding environment of the load equipment, an operation mode determination unit to determine an operation mode of the leakage current sensor at an operation mode for leakage detection in normal times or an operation mode for abnormality diagnosis based on a condition signal outputted from the equipment condition acquisition unit, a leakage current sensor drive unit to make the leakage current sensor operate in the operation mode determined by the operation mode determination unit, and a diagnosis unit to make the diagnosis based on the detection signal outputted from the leakage current sensor and the condition signal outputted from the equipment condition acquisition unit. When the equipment condition satisfies a predetermined switching condition while the leakage current sensor is operating in the operation mode for leakage detection in normal times, the operation mode determination unit switches the operation mode of the leakage current sensor to the operation mode for abnormality diagnosis.

An equipment diagnosis system according to another aspect of the present disclosure includes the aforementioned equipment diagnosis device and a server that communicates with the equipment diagnosis device via a network. The server makes the diagnosis on the aforementioned load equipment by operating in cooperation with the aforementioned diagnosis unit.

### Effect of the Invention

According to the present disclosure, the equipment diagnosis device and the equipment diagnosis system that realize a low cost, easy diagnosis on the load equipment, and high reliability of the diagnosis can be provided.

### BRIEF DESCRIPTION OF THE DRAWINGS

FIG. 1 is a configuration diagram showing the configuration of an equipment diagnosis device according to a first embodiment.

FIG. 2 is a perspective view showing an example of the configuration of a leakage current sensor shown in FIG. 1.

FIG. 3 is a diagram showing an example of arrangement of the leakage current sensor shown in FIG. 2 on electric paths.

FIG. 4(A) is a B-H curve of a magnetic core shown in FIGS. 2 and 3.

FIG. 4(B) is a graph showing a waveform of an excitation magnetic field in the magnetic core when the current value of a zero-phase current is 0.

FIG. 4(C) is a graph showing the time variation of magnetic flux passing through the magnetic core when the current value of the zero-phase current is 0.

FIG. 4(D) is a graph showing a waveform of voltage outputted from a detection coil when the current value of the zero-phase current is 0.

FIG. 5(A) is a B-H curve of the magnetic core shown in FIGS. 2 and 3.

FIG. 5(B) is a graph showing the waveform of the excitation magnetic field in the magnetic core when the current value of the zero-phase current is not 0.

FIG. 5(C) is a graph showing the time variation of the magnetic flux passing through the magnetic core when the current value of the zero-phase current is not 0.

FIG. 5(D) is a graph showing the waveform of the voltage outputted from the detection coil when the current value of the zero-phase current is not 0.

FIG. 6 is a block diagram showing the configuration of a control device shown in FIG. 1.

FIG. 7(A) is a diagram showing an example of the hardware configuration of the equipment diagnosis device according to the first embodiment.

FIG. 7(B) is a diagram showing another example of the hardware configuration of the equipment diagnosis device according to the first embodiment.

FIG. 8 is a flowchart showing the operation of the equipment diagnosis device according to the first embodiment.

FIG. 9 is a block diagram showing the configuration of an equipment diagnosis device according to a modification of the first embodiment.

FIG. 10 is a block diagram showing the configuration of an equipment diagnosis device according to a second embodiment.

FIG. 11 is a block diagram showing another example of the configuration of the equipment diagnosis device according to the second embodiment.

FIG. 12 is a diagram showing an example of operation sequences of the leakage current sensor of the equipment diagnosis device according to the second embodiment.

FIG. 13 is a block diagram showing the configuration of an equipment diagnosis system according to a third embodiment.

FIG. 14 is a block diagram showing another example of the configuration of the equipment diagnosis system according to the third embodiment.

FIG. 15 is a block diagram showing the configuration of an equipment diagnosis system according to a modification of the third embodiment.

FIG. 16 is a block diagram showing another example of the configuration of the equipment diagnosis system according to the modification of the third embodiment.

FIG. 17 is a block diagram showing another example of the configuration of an equipment diagnosis system according to a fourth embodiment.

FIG. 18 is a block diagram showing another example of the configuration of the equipment diagnosis system according to the fourth embodiment.

FIG. 19 is a block diagram showing the configuration of an equipment diagnosis system according to a modification of the fourth embodiment.

FIG. 20 is a block diagram showing another example of the configuration of the equipment diagnosis system according to the modification of the fourth embodiment.

### MODE FOR CARRYING OUT THE INVENTION

An equipment diagnosis device and an equipment diagnosis system according to each embodiment of the present disclosure will be described below with reference to the drawings. The following embodiments are just examples and it is possible to appropriately combine embodiments and appropriately modify each embodiment.

### First Embodiment

### <Configuration of Equipment Diagnosis Device 100>

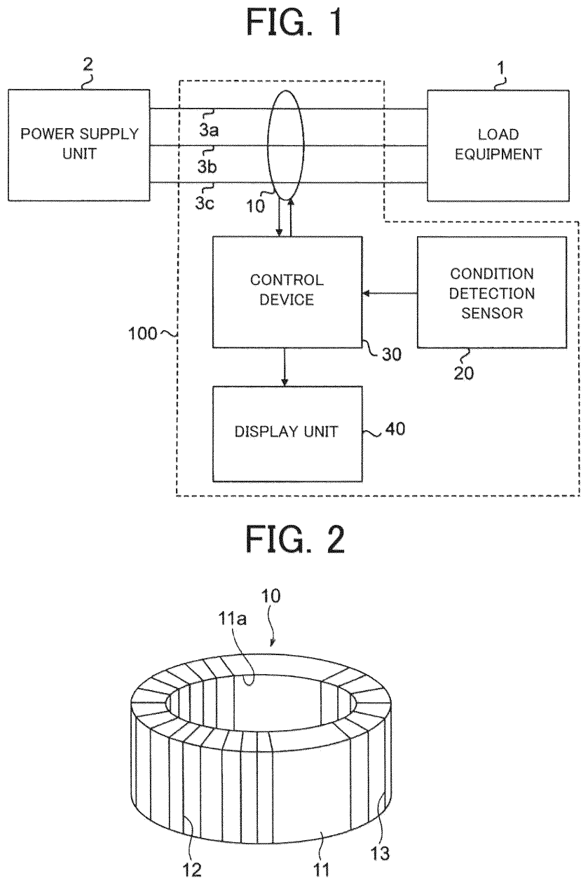

FIG. 1 is a configuration diagram showing the configuration of an equipment diagnosis device 100 according to a first embodiment. As shown in FIG. 1, the equipment diagnosis device 100 is a device that makes a diagnosis on load equipment 1 that is driven by electric power supplied from a power supply unit 2. The equipment diagnosis device 100 is an abnormality diagnosis device that diagnoses the presence or absence of abnormality in the load equipment 1.

In the first embodiment, the description will be given by taking an example in which the load equipment 1 is driven by three-phase AC power. In this case, the three-phase AC power is supplied to the load equipment 1 through a plurality of (e.g., 3 or 4) electric cables 3a, 3b, 3c as electric paths. Incidentally, in cases where the load equipment 1 is driven by single-phase AC power, the number of electric wires connecting the power supply unit 2 and the load equipment 1 is 2 or 3. Further, a ground wire, an earth wire and a neutral wire of the power supply unit 2 may be connected to the load equipment 1.

The load equipment 1 is, for example, a motor, industrial equipment or an industrial machine including the motor, business electric equipment, IT (Information Technology) equipment, OA (Office Automation) equipment, home electric equipment or illumination equipment, or the like. In the first embodiment, the description will be given by taking an example in which the load equipment 1 is a motor.

The equipment diagnosis device 100 includes one leakage current sensor 10, a condition detection sensor 20 as an equipment condition acquisition unit, a control device 30 as a control unit, and a display unit 40 as a notification unit.

### <Configuration of Leakage Current Sensor 10>

FIG. 2 is a perspective view showing an example of the configuration of the leakage current sensor 10 shown in FIG. 1. The leakage current sensor 10 outputs a detection signal in a waveform corresponding to currents flowing in the electric cables 3a-3c (sum total of the currents flowing in the electric cables 3a-3c). That is, when the sum total of the currents flowing in the electric cables 3a-3c is not zero, it means that the leakage has occurred in an electric path. The leakage current sensor 10 is a sensor of the so-called active type. The leakage current sensor 10 is a current sensor employing a flux gate-type magnetic sensor, for example.

The leakage current sensor 10 includes a magnetic core 11 in a cylindrical shape as a core part, an excitation coil 12 as a first coil, and a detection coil 13 as a second coil. The excitation coil 12 and the detection coil 13 are wound around the magnetic core 11.

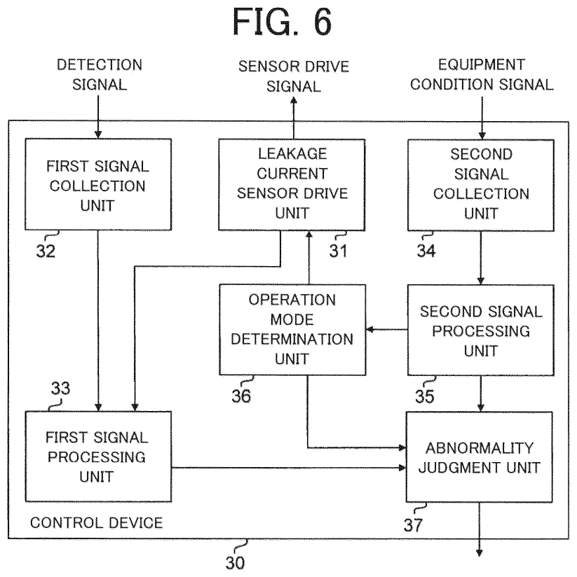

A sensor drive signal outputted from a leakage current sensor drive unit 31 shown in FIG. 6 which will be explained later is applied to the excitation coil 12. The sensor drive signal is an AC current signal, for example. An AC current (hereinafter referred to also as an “excitation current”) as a drive current flows into the excitation coil 12, by which the magnetic core 11 periodically undergoes magnetic saturation. The detection coil 13 outputs a signal representing induced electromotive force occurring when the excitation current flows in the excitation coil 12 as the detection signal. Incidentally, the leakage current sensor 10 can also be a sensor of a different type as long as the leakage current sensor 10 is a sensor that operates based on the sensor drive signal outputted from the leakage current sensor drive unit 31 (see FIG. 6). For example, the leakage current sensor 10 can also be a current sensor employing a high-sensitivity magnetic sensor or magnetic sensor device or a current sensor employing an optical fiber.

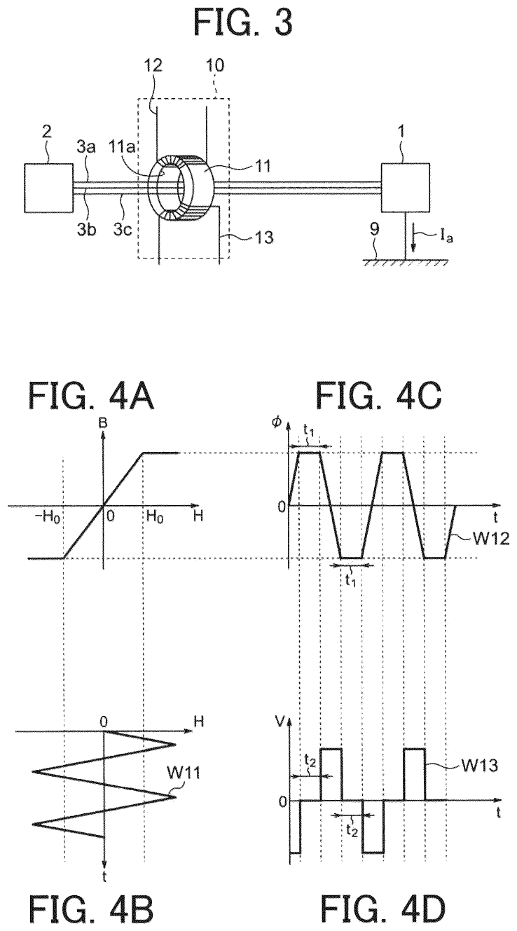

FIG. 3 is a diagram showing an example of arrangement of the leakage current sensor 10 shown in FIG. 2 on the electric cables 3a-3c. As shown in FIG. 3, the leakage current sensor 10 is arranged so that the electric cables 3a-3c penetrate a hollow part 11a of the magnetic core 11. The leakage current sensor 10 detects a zero-phase current as the sum total of the three-phase currents flowing in the electric cables 3a-3c. Here, the zero-phase current is equivalent to a leak current Ia that flows from the electric cables 3a-3c and the load equipment 1 to the ground 9 via insulation resistance and floating capacitance. Incidentally, an example in which the leak current Ia flows from the load equipment 1 to the ground 9 is shown in FIG. 3. In the following description, the zero-phase current is described while assigning a reference character I_{d} thereto.

In FIGS. 2 and 3, an example in which the excitation coil 12 and the detection coil 13 are wound around part of the magnetic core 11 and the number of turns of the excitation coil 12 is greater than the number of turns of the detection coil 13 is shown in order to facilitate the understanding of the description. Incidentally, it is also permissible even if the excitation coil 12 and the detection coil 13 are evenly wound around the whole circumference of the magnetic core 11 in order to inhibit fluctuation of the output due to winding unevenness and an external magnetic field. Further, the numbers of turns of the excitation coil 12 and the detection coil 13 are also not limited to those shown in FIGS. 2 and 3. For example, it is also permissible even if the number of turns of the detection coil 13 is greater that the number of turns of the excitation coil 12 or the number of turns of the excitation coil 12 is the same as the number of turns of the detection coil 13.

Further, while the excitation coil 12 and the detection coil 13 are wound directly on the magnetic core 11 in the example shown in FIGS. 2 and 3, it is also permissible even if the excitation coil 12 and the detection coil 13 are wound on an exterior surface of a case made of resin and encapsulating the magnetic core 11. With this configuration, properties of the magnetic core 11 can be prevented from being deteriorated by winding stress as stress occurring in the magnetic core 11 when the excitation coil 12 and the detection coil 13 are wound around the magnetic core 11. Furthermore, while the excitation coil 12 and the detection coil 13 are magnetically coupled with each other via the magnetic core 11, it is also possible to couple the excitation coil 12 and the detection coil 13 with the magnetic core 11 as a single coil. Moreover, the leakage current sensor 10 can also be a leakage current sensor of a clamp opening/closing type in which the magnetic core 11 in the cylindrical shape is provided with an opening/closing function.

The leakage current sensor 10 is connected to the leakage current sensor drive unit 31 and a first signal collection unit 32 shown in FIG. 6 which will be explained later. Specifically, the excitation coil 12 of the leakage current sensor 10 is connected to the leakage current sensor drive unit 31, while the detection coil 13 of the leakage current sensor 10 is connected to the first signal collection unit 32.

### <Operating Principle of Leakage Current Sensor 10>

Next, an operating principle of the leakage current sensor 10 will be described below. First, the operating principle of the leakage current sensor 10 when the current value of the zero-phase current I_{d} is 0 will be described by using FIGS. 4(A) to 4(D). FIG. 4(A) is a B-H curve indicating a magnetic property of the magnetic core 11 shown in FIGS. 2 and 3. In FIG. 4(A), the vertical axis represents the magnitude of the magnetic flux density B, and the horizontal axis represents the magnitude of an excitation magnetic field (hereinafter referred to also as an “AC magnetic field H”) occurring when an excitation current (AC current) flows in the excitation coil 12. As shown in FIG. 4(A), in the magnetic core 11, the magnetic flux density B is saturated when the magnitude of the AC magnetic field H reaches a saturation magnetic field H₀, −H₀.

FIG. 4(B) is a graph showing a waveform W11 of the AC magnetic field H in the magnetic core 11 when the current value of the zero-phase current I_{d} is 0. When the excitation coil 12 shown in FIGS. 2 and 3 is energized with an excitation current in the shape of a triangular wave, the waveform W11 of the AC magnetic field H takes on a waveform that is positive-negative symmetrical. Incidentally, let N₁ represent the number of turns of the excitation coil 12, I represent the excitation current, and r represent an average radius of the magnetic core 11, the AC magnetic field H is represented by the following expression (1):

$$H = \frac{{N}_{1} I}{2 π r} \qquad ( 1 )$$

Here, let S represent the cross-sectional area of the magnetic core 11 and Φ represent magnetic flux passing through the magnetic core 11, the magnetic flux Φ is the product of the magnetic flux density B and the cross-sectional area S. FIG. 4(C) is a graph W12 showing the time variation of the magnetic flux Φ passing through the magnetic core 11 when the current value of the zero-phase current I_{d} is 0. As shown in FIGS. 4(A) and 4(C), when the magnetic flux density B in the magnetic core 11 is saturated, the time variation of the magnetic flux Φ is 0. As shown in FIG. 4(C), when the current value of the zero-phase current I_{d} is 0, a period t₁ in which the time variation is 0 when the magnetic flux Φ is positive is equal to a period t₁ in which the time variation is 0 when the magnetic flux Φ is negative.

Next, when the current value of the zero-phase current I_{d} is 0, let V represent an output voltage representing the induced electromotive force occurring to the detection coil 13 (see FIGS. 2 and 3) and N₂ represent the number of turns of the detection coil 13, the output voltage V is represented by the following expression (2) according to Faraday's law of electromagnetic induction:

$$V = {N}_{2} \frac{d Φ}{dt} = {N}_{2} \frac{d ( B S )}{dt} \qquad ( 2 )$$

Here, the cross-sectional area S of the magnetic core 11 is a constant. Further, let μ represent the magnetic permeability of the magnetic core 11, the expression (2) can be transformed to the following expression (3) since the magnetic flux density B is the product of the magnetic permeability μ and the AC magnetic field H:

$$V = {N}_{2} μ S \frac{dH}{dt} = {N}_{2} {μ}_{0} {μ}_{r} S \frac{dH}{dt} \qquad ( 3 )$$

In the expression (3), μ₀ represents the magnetic permeability of the vacuum, and μᵣ represents the relative permeability of the magnetic core 11. In the first embodiment, the magnetic permeability μ₀ of the vacuum is 4π×10⁻⁷ (H/m), for example. As shown in the aforementioned expression (2), the output voltage V is proportional to the time variation of the magnetic flux Φ. The output voltage V corresponding to the time variation of the magnetic flux density B is obtained since the magnetic flux Φ is the product of the magnetic flux density B and the cross-sectional area S of the magnetic core 11 and the cross-sectional area S is a constant.

FIG. 4(D) is a graph showing a waveform W13 of the output voltage V when the current value of the zero-phase current I_{d} is 0. As shown in FIGS. 4(A), 4(C) and 4(D), when the time variation of the magnetic flux density B is 0, that is, when the magnetic flux density B is saturated, the output voltage V is also 0. Since the B-H curve of the magnetic core 11 is a curve symmetrical with respect to the origin as shown in FIG. 4(A), a period in which the output voltage V is 0 is repeated at a cycle corresponding to twice the frequency of the AC magnetic field H. As shown in FIG. 4(D), an interval t₂ in which the output voltage V is 0 when the variation of the magnetic flux Φ is positive is equal to an interval t₂ in which the output voltage V is 0 when the variation of the magnetic flux Φ is negative.

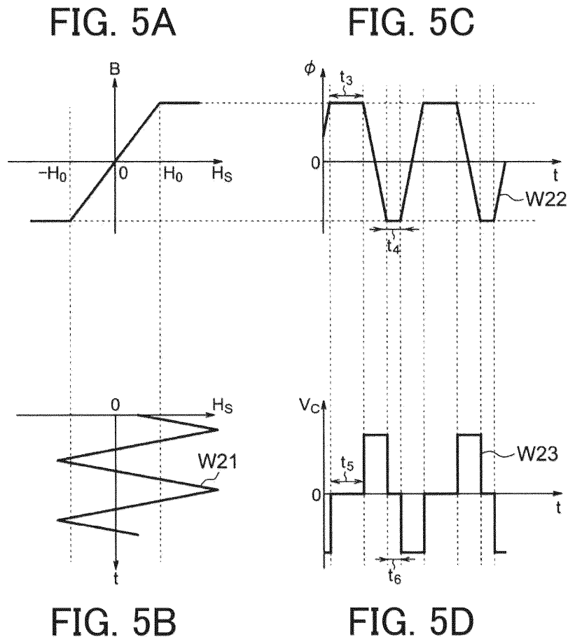

Next, the operating principle of the leakage current sensor 10 when the current value of the zero-phase current I_{d} is not 0 will be described by using FIGS. 5(A) to 5(D). In the following description, an excitation magnetic field occurring to the magnetic core 11 (see FIGS. 2 and 3) due to the zero-phase current I_{d} is represented as H_{d}. The excitation magnetic field H_{d} is represented by the following expression (4) according to Ampere's law. In the expression (4), r represents the average radius of the magnetic core 11.

$${H}_{d} = \frac{{I}_{d}}{2 π r} \qquad ( 4 )$$

FIG. 5(A) is a graph showing a B-H curve of the magnetic core 11 shown in FIGS. 2 and 3. In FIG. 5(A), the vertical axis represents the magnitude of the magnetic flux density B, and the horizontal axis represents the magnitude of an excitation magnetic field Hₛ. The excitation magnetic field Hₛ is the sum of the AC magnetic field H occurring when the excitation current flows in the excitation coil 12 and the aforementioned excitation magnetic field H_{d}. When the current value of the zero-phase current I_{d} is not 0, in the magnetic core 11, the magnetic flux density B is saturated when the magnitude of the excitation magnetic field Hₛ reaches the saturation magnetic field H₀, −H₀ similarly to the case of FIG. 4(A).

FIG. 5(B) is a graph showing a waveform W21 of the excitation magnetic field Hₛ applied to the magnetic core 11 when the current value of the zero-phase current I_{d} is not 0. Here, in cases where the zero-phase current I_{d} is a DC current, the excitation magnetic field H_{d} occurring due to the DC current is superimposed on the AC magnetic field H as a DC bias magnetic field. Therefore, the waveform W21 of the excitation magnetic field Hₛ takes on a waveform that is positive-negative unsymmetrical as shown in FIG. 5(B).

FIG. 5(C) is a graph W22 showing the time variation of the magnetic flux Φ passing through the magnetic core 11 when the current value of the zero-phase current I_{d} is not 0. As shown in FIG. 5(C), when the current value of the zero-phase current I_{d} is not 0, a period t₃ in which the time variation is 0 when the magnetic flux Φ is positive is unequal to a period t₄ in which the time variation is 0 when the magnetic flux Φ is negative. This is because the waveform W21 of the excitation magnetic field Hₛ shown in FIG. 5(B) takes on a positive-negative unsymmetrical waveform.

FIG. 5(D) is a graph showing a waveform W23 of the output voltage V occurring to the detection coil 13 when the current value of the zero-phase current I_{d} is not 0. As shown in FIG. 5(D), when the current value of the zero-phase current I_{d} is not 0, an interval in which the output voltage V is 0 is not constant. Specifically, an interval t₅ shown in FIG. 5(D) in which the output voltage V is 0 when the variation of the magnetic flux Φ is positive is longer than an interval t₆ in which the output voltage V is 0 when the variation of the magnetic flux Φ is negative.

The variation in the output voltage V shown in FIG. 5(D) is obtained at a cycle corresponding to twice the frequency f of the excitation magnetic field Hₛ. Therefore, the zero-phase current I_{d} (i.e., the leak current) as a measured current can be calculated by extracting only a component (i.e., second harmonic component) V_{2f} corresponding to twice the frequency f of the excitation magnetic field Hₛ from the waveform W23 of the output voltage V shown in FIG. 5(D). Incidentally, a lock-in amplifier synchronized with the control of the excitation magnetic field Hₛ may be used for the extraction of the second harmonic component V_{2f}. Further, a bandpass filter constructed with an analog circuit or a digital filter constructed with a digital circuit may be used for the extraction of the second harmonic component V_{2f}. It is also possible to extract a particular frequency component calculated by a Fourier operation by using a microcomputer as the second harmonic component V_{2f}.

Next, the relationship between the zero-phase current I_{d} and the output voltage V occurring to the detection coil 13 will be described below. The following expression (5) is obtained by performing Fourier series expansion on the waveform W23 of the output voltage V shown in FIG. 5(D). In the expression (5), n is an integer larger than or equal to 1.

$${V}_{c} = \frac{{a}_{0}}{2} + {\sum }_{n = 1}^{∞} ( {a}_{n} cos nx + {b}_{n} sin nx ) \qquad ( 5 )$$

In the expression (5), when n is an even number, the Fourier coefficient a₀=0 and the Fourier coefficient aₙ=0. Further, the n-th harmonic component V_{nf} of the output voltage V_{c} is represented by the following expression (6):

$${V}_{nf} = 8 {μ}_{0} {μ}_{r} {SN}_{2} {fH}_{0} \frac{sin ( \frac{n π}{2} \frac{{H}_{0}}{{H}_{m}} )}{\frac{n π}{2} \frac{{H}_{0}}{{H}_{m}}} sin ( \frac{n π}{2} ( 1 + \frac{{H}_{d}}{{H}_{m}} ) ) \qquad ( 6 )$$

In the expression (6), f represents the frequency of the excitation magnetic field Hₛ, H₀ represents the saturation magnetic field of the magnetic core 11, and Hₘ represents the maximum value of the excitation magnetic field Hₛ. By substituting n=2 into the expression (6), the following expression (7) is obtained:

$${V}_{2 f} = 8 {μ}_{0} {μ}_{r} {SN}_{2} {fH}_{d} sin ( π \frac{{H}_{0}}{{H}_{m}} ) sin c ( π \frac{{H}_{d}}{{H}_{m}} ) \qquad ( 7 )$$

By substituting the aforementioned expression (4) into the expression (7), the following expression (8) is obtained:

$${V}_{2 f} = \frac{8 {μ}_{0} {μ}_{r} {SN}_{2} {fI}_{d}}{2 π r} sin ( π \frac{{H}_{0}}{{H}_{m}} ) sin c ( π \frac{{H}_{d}}{{H}_{m}} ) \qquad ( 8 )$$

As shown in the expression (8), the second harmonic component V_{2f} of the output voltage V_{c} is proportional to the zero-phase current I_{d}. Further, as shown in the expressions (7) and (8), the second harmonic component V_{2f} is dependent on the frequency f of the excitation magnetic field Hₛ, the number N₂ of turns of the detection coil 13, the maximum value Hₘ of the excitation magnetic field Hₛ, the saturation magnetic field H₀ of the magnetic core 11, the relative permeability μᵣ of the magnetic core 11, the cross-sectional area S of the magnetic core 11, and so forth.

While the calculation of the expression (8) was explained by taking an example in which the waveform of the excitation magnetic field Hₛ is a triangular wave, even when the waveform of the excitation magnetic field Hₛ is a sinusoidal wave, the parameters on which the second harmonic component V_{2f} is dependent are the same even though the coefficients are different. Further, while the calculation of the expression (8) was explained by taking an example in which the zero-phase current I_{d} is a DC current, the calculation is possible even when the zero-phase current I_{d} is an AC current by adjusting a sampling condition. The sampling condition is, for example, the frequency of the excitation magnetic field Hₛ should be set higher than or equal to twice the frequency of the zero-phase current I_{d}.

### <Configuration of Condition Detection Sensor 20>

Next, the configuration of the aforementioned condition detection sensor 20 shown in FIG. 1 will be described below. The condition detection sensor 20 obtains a physical quantity indicating the condition of the load equipment 1. The condition detection sensor 20 is, for example, a vibration sensor that measures vibration of the load equipment 1. Incidentally, the condition detection sensor 20 can also be a temperature sensor or infrared sensor that measures the temperature of the load equipment 1. The temperature sensor or infrared sensor detects an overheated region of the load equipment 1. Further, the condition detection sensor 20 can also be a motion sensor that detects motion of the load equipment 1.

Furthermore, the condition detection sensor 20 can also be an electromagnetic wave sensor that detects the presence or absence of electric discharge in the load equipment 1. The electromagnetic wave sensor includes a coil or a magnetic sensor, for example, and thereby detects electromagnetic wave noise caused by electric discharge. The condition detection sensor 20 can also be an abnormal noise sensor (e.g. microphone) that detects abnormal noise (referred to also as “abnormal sound”) when the load equipment 1 is in operation. The condition detection sensor 20 can also be a water leakage current sensor that detects the presence or absence of water leakage in the load equipment 1 or an oil leakage current sensor that detects the presence or absence of oil leakage in the load equipment 1. The condition detection sensor 20 can also be a smoking sensor that detects the presence or absence of smoking in the load equipment 1. Incidentally, the condition detection sensor 20 may be arranged in any method as long as the condition of the load equipment 1 can be detected directly or indirectly.

Further, the condition detection sensor 20 as the equipment condition acquisition unit can also be a noise meter that detects the presence or absence of electromagnetic noise emission related to EMC (Electromagnetic Compatibility) in the outputs of the load equipment 1 and the power supply unit. The noise meter includes a coil or an antenna (e.g., dipole antenna, Yagi antenna (registered trademark) or the like) adapted to the frequency of the noise, for example, and thereby detects the electromagnetic noise related to EMC propagating in space and increasing due to deterioration of various filters installed in output parts of the load equipment 1 and the power supply unit. Further, since the electromagnetic noise related to EMC propagates also via the power supply, a signal and a ground line (wiring), the noise meter can also be a noise meter having a function of a voltage reader supporting the reading of high-frequency waves.

### <Configuration of Control Device 30>

Next, the configuration of the control device 30 will be described below. FIG. 6 is a block diagram showing the configuration of the control device 30 according to the first embodiment. As shown in FIG. 6, the control device 30 includes the leakage current sensor drive unit 31, the first signal collection unit 32 and a first signal processing unit 33.

The leakage current sensor drive unit 31 controls the current value of the excitation current for energizing the excitation coil 12 (see FIGS. 2 and 3), the frequency f of the excitation current, and the waveform of the excitation current. Incidentally, the leakage current sensor drive unit 31 may also be configured to control at least one of the current value of the excitation current, the frequency f of the excitation current, or the waveform of the excitation current.

The first signal collection unit 32 is a signal input unit to which a signal indicating the output voltage (hereinafter referred to also as a “detection signal”) outputted from the detection coil 13 is inputted. The first signal collection unit 32 may acquire the detection signal outputted from the leakage current sensor 10 in a desired signal format. For example, in cases where the detection signal is an analog signal, the first signal collection unit 32 may convert the analog signal to a digital signal.

The first signal processing unit 33 extracts the second harmonic component of a detection voltage signal stored in the first signal collection unit 32 based on the detection voltage signal and a driving condition of the leakage current sensor 10. The first signal processing unit 33 needs to be driven according to the frequency f of the excitation current outputted from the leakage current sensor drive unit 31. By synchronizing the leakage current sensor drive unit 31 and the first signal processing unit 33 with each other as above, it is possible to adjust the magnitude of the sensor output corresponding to the zero-phase current detected by the leakage current sensor 10 (see FIG. 1) (i.e., current detection sensitivity) and a frequency range of the detectable zero-phase current. That is, a measurement dynamic range of the leakage current sensor 10 can be adjusted. Incidentally, the first signal processing unit 33 may either directly measure the time variation of the aforementioned output voltage V_{c} shown in FIG. 5(D) or measure the time until the magnetic core 11 reaches the magnetic saturation.

The control device 30 further includes a second signal collection unit 34 and a second signal processing unit 35.

The second signal collection unit 34 is a signal input unit to which a condition signal indicating the condition of the load equipment 1 (hereinafter referred to also as an “equipment condition signal”) outputted from the condition detection sensor 20 is inputted. The second signal collection unit 34 may acquire the signal outputted from the condition detection sensor 20 in a desired signal format. For example, the second signal collection unit 34 may convert an analog signal outputted from the condition detection sensor 20 to a digital signal.

The second signal processing unit 35 extracts a feature value from the equipment condition signal stored in the second signal collection unit 34. For example, the second signal processing unit 35 calculates an amplitude value or an effective value of the waveform of the output signal. Further, the second signal processing unit 35 may calculate a value exceeding a predetermined threshold value as the feature value. Furthermore, the second signal processing unit 35 may calculate the feature value by analysis of a frequency spectrum or main frequency components.

Here, the current value of the leak current flowing in the electric cables 3a-3c can increase or decrease depending on the condition of the load equipment 1. Further, there are cases where variation in the leak current corresponding to variation in the condition of the load equipment 1 cannot be detected by using rated sensitivity current of the leak current for performing the insulation monitoring for human body protection, fire prevention, and so forth.

Specifically, the rated sensitivity current varies depending on the purpose of performing the insulation monitoring by using the leakage current sensor 10 or the use for the leakage current sensor 10. For example, when the purpose of performing the insulation monitoring is human body protection, 5 mA or 30 mA is used as the rated sensitivity current. Further, a current range in which the leakage current sensor 10 performs a breaking operation varies depending on the rating of the leakage current sensor 10. For example, specifications have been determined so that the leakage current sensor 10 operates in an operating current range of 4 mA to 6 mA when the rated sensitivity current is 5 mA and operates in an operating current range of 15 mA to 30 mA when the rated sensitivity current is 30 mA, and thus the sensitivity of the leakage current sensor 10 is a fixed value. Incidentally, although there are cases where the sensitivity can be adjusted by adjusting the gain of a booster amplifier provided after the leakage current sensor by using a sensitivity adjustment trimmer or a sensitivity adjustment dial provided on the leakage current sensor, it is difficult to frequently adjust the sensitivity in a normal operation condition.

In the first embodiment, the control device 30 further includes an operation mode determination unit 36 and an abnormality judgment unit 37 as a diagnosis unit.

The operation mode determination unit 36 determines an operation mode of the leakage current sensor 10 at an operation mode for leakage detection as an operation mode in normal times or an operation mode for abnormality diagnosis based on the equipment condition signal outputted from the condition detection sensor 20. The operation mode determination unit 36 determines (sets) the operation mode of the leakage current sensor 10 based on the feature value of the equipment condition signal provided via the second signal collection unit 34 and the second signal processing unit 35. The operation mode determination unit 36 outputs an operation mode setting signal indicating the determined operation mode to the leakage current sensor drive unit 31. The leakage current sensor drive unit 31 controls at least one of the current value of the excitation current for energizing the excitation coil 12 (see FIGS. 2 and 3), the frequency f of the excitation current, or the waveform of the excitation current based on the operation mode setting signal. By this control, the leakage current sensor drive unit 31 makes the leakage current sensor 10 operate in the operation mode determined by the operation mode determination unit 36.

In the following description, the operation mode for leakage detection in normal times is referred to also as a “normal monitoring mode”, and the operation mode for abnormality diagnosis is referred to also as an “abnormality diagnosis mode”. The “normal monitoring mode” is a mode for monitoring the operation condition of the load equipment 1 in normal times. The “abnormality diagnosis mode” is a mode for measuring the leak current by adjusting the measurement dynamic range of the leakage current sensor 4 in order to make the abnormality diagnosis on the load equipment 1. Here, the measurement dynamic range means the current detection sensitivity and the frequency range of the leakage current sensor 10. The measurement dynamic range in the “abnormality diagnosis mode” is wider than the measurement dynamic range in the “normal monitoring mode”.

Next, a description will be given of an example in which the operation mode determination unit 36 adjusts the dynamic range of the leakage current sensor 10 depending on the operation mode. The measurement dynamic range when the operation mode is the “normal monitoring mode” is a first dynamic range for normal monitoring. The first dynamic range is a dynamic range in which the detection sensitivity is low and the frequency range is narrow. For example, in the first dynamic range, the setting may be made like rated current=300 mA and frequency=50 Hz/60 Hz.

The measurement dynamic range when the operation mode is the “abnormality diagnosis mode” is a second dynamic range for leakage detection. The second dynamic range is a dynamic range in which the detection sensitivity is high and the frequency range is wide. For example, in the second dynamic range, the setting may be made like rated current=10 mA and frequency=DC−10 kHz.

When the operation mode determination unit 36 has set the operation mode of the leakage current sensor 10 at the “normal monitoring mode”, the leakage current sensor drive unit 31 sets the measurement dynamic range of the leakage current sensor 10 at the aforementioned “first dynamic range” by controlling the sensor drive signal outputted to the excitation coil 12 (see FIG. 2). In this case, the first signal processing unit 33 detects the current value of the zero-phase current based on the output signal of the detection coil 13 provided from the first signal collection unit 32. The abnormality judgment unit 37 determines the presence or absence of abnormality of the load equipment 1 based on the current value of the abnormality current.

When the operation mode determination unit 36 has switched the operation mode of the leakage current sensor 10 to the “abnormality diagnosis mode”, the leakage current sensor drive unit 31 sets the measurement dynamic range of the leakage current sensor 10 at the aforementioned “second dynamic range” by controlling the sensor drive signal outputted to the excitation coil 12 (see FIG. 2). In this case, the first signal processing unit 33 may synchronize the output signal of the detection coil 13 provided from the first signal collection unit 32 and the sensor drive signal with each other and extract only particular frequency components. The operation mode determination unit 36 adjusts the measurement dynamic range of the leakage current sensor 10 by adjusting the current detection sensitivity of the leakage current sensor 10, for example. Further, the operation mode determination unit 36 may adjust the measurement dynamic range of the leakage current sensor 10 by adjusting the frequency range of the leakage current sensor 10. Furthermore, the operation mode determination unit 36 may adjust the measurement dynamic range of the leakage current sensor 10 by adjusting both of the current detection sensitivity and the frequency range of the leakage current sensor 10.

The operation mode determination unit 36 outputs a signal indicating a judgment result, specifically, a signal indicating a result of judgment on the presence or absence of the switching of the operation mode, to the abnormality judgment unit 37.

The abnormality judgment unit 37 determines the presence or absence of abnormality in the load equipment 1 based on a signal outputted from the first signal processing unit 33, a signal outputted from the second signal processing unit 35, and the signal indicating the judgment result outputted from the operation mode determination unit 36. As above, the abnormality judgment unit 37 diagnoses the presence or absence of abnormality in the load equipment 1 based on information outputted from a plurality of sensors of different types. Therefore, the reliability of the diagnosis by the equipment diagnosis device 100 can be increased. As above, in the equipment diagnosis device 100, the leakage current sensor 10 and the condition detection sensor 20 operate in cooperation with each other for the judgment on the presence or absence of abnormality in the load equipment 1.

### <Configuration of Display Unit 40>

Next, returning to FIG. 1, the configuration of the display unit 40 will be described below. The display unit 40 notifies of the result of the diagnosis by the abnormality judgment unit 37 (i.e., the result of the judgment on the presence or absence of abnormality). The display unit 40 is, for example, a display or the like that displays information indicating the judgment result. Incidentally, the equipment diagnosis device 100 may include security equipment such as a breaker, a relay or a warning buzzer as the notification unit instead of the display unit 40. As above, the equipment diagnosis device 100 may notify a user of the judgment result of the abnormality judgment unit 37 by a means corresponding to an operation method of the load equipment 1 after the abnormality diagnosis.

Incidentally, in FIGS. 1 and 6, the connection mode of the components of the equipment diagnosis device 100 may be either wired or wireless. Further, the equipment diagnosis device 100 may include not only a single condition detection sensor 20 but also a plurality of condition detection sensors 20. The equipment diagnosis device 100 may include a plurality of condition detection sensors 20 of different types. Furthermore, inverter control equipment may be provided between the load equipment 1 and the power supply unit 2 shown in FIG. 1. With such a configuration, the equipment diagnosis device 100 can be applied to an electric circuit capable of varying the frequency of the three-phase alternating current. Further, if the power supply unit 2 is a DC power supply such as a solar cell or a fuel cell, the equipment diagnosis device 100 can be applied to an electric circuit in which direct current flows.

### <Hardware Configuration>

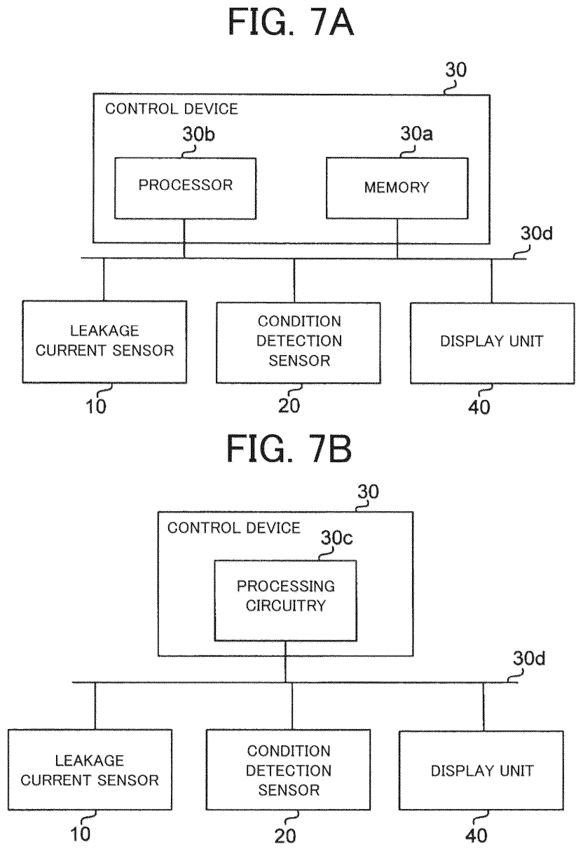

Next, the hardware configuration of the equipment diagnosis device 100 will be described below. FIG. 7(A) is a diagram schematically showing the hardware configuration of the equipment diagnosis device 100. As shown in FIG. 7(A), the control device 30 of the equipment diagnosis device 100 can be implemented by using a memory 30a as a storage device that stores a program as software and a processor 30b as an information processing unit that implements the program stored in the memory 30a (e.g., by a computer), for example. The leakage current sensor 10, the condition detection sensor 20 and the display unit 40 are connected to the processor 30b via a bus 30d. Incidentally, part of the components of the control device 30 may be implemented by the memory 30a shown in FIG. 7(A) and the processor 30b executing a program. Further, the control device 30 may also be implemented by electric circuitry.

FIG. 7(B) is a diagram schematically showing another example of the hardware configuration of the equipment diagnosis device 100. As shown in FIG. 7(B), the control device 30 may also be implemented by using processing circuitry 30c as dedicated hardware such as a single circuit or a combined circuit. In this case, the functions of the control device 30 are implemented by the processing circuitry 30c.

### <Operation>

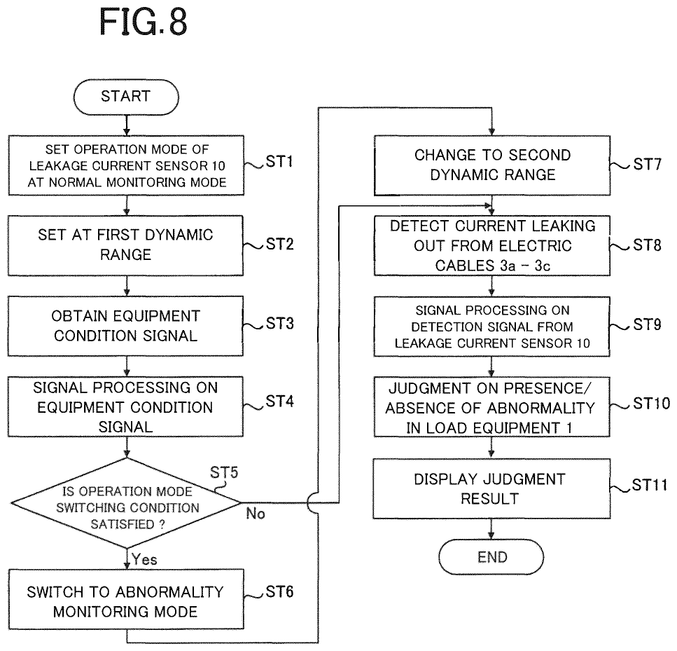

Next, the operation of the equipment diagnosis device 100 according to the first embodiment will be described below. FIG. 8 is a flowchart showing the operation of the equipment diagnosis device 100 according to the first embodiment. An example in which the operation mode of the leakage current sensor 10 is switched from the “normal monitoring mode” to the “abnormality diagnosis mode” will be described below.

First, in step ST1, the leakage current sensor drive unit 31 sets the operation mode of the leakage current sensor 10 at the “normal monitoring mode”.

In step ST2, the operation mode determination unit 36 sets the measurement dynamic range of the leakage current sensor 10 at the aforementioned first dynamic range.

In step ST3, the condition detection sensor 20 obtains the equipment condition signal as the signal indicating the condition of the load equipment 1.

In step ST4, the second signal processing unit 35 performs signal processing (e.g., conversion to a digital signal or the like) on the equipment condition signal provided from the condition detection sensor 20.

In step ST5, the operation mode determination unit 36 determines whether or not the equipment condition signal provided from the second signal processing unit 35 satisfies a predetermined switching condition. When the operation mode determination unit 36 determines that the switching condition is satisfied (i.e., when the judgment is Yes in the step ST5), the process advances to step ST6.

In the case where the condition detection sensor 20 is a vibration sensor, the operation mode determination unit 36 is capable of acquiring a signal corresponding to vibration that occurs in the load equipment 1, that is, a signal corresponding to amplitude of speed (unit: m/s) of the load equipment 1. The operation mode determination unit 36 switches the operation mode of the leakage current sensor 10 based on the signal outputted from the vibration sensor. For example, when the magnitude of the amplitude of the signal is greater than or equal to a predetermined threshold value Th, the operation mode determination unit 36 determines that the switching condition is satisfied and switches the operation mode of the leakage current sensor 10 to the “abnormality diagnosis mode”. Incidentally, the vibration sensor may detect a displacement amount (unit: m) or acceleration (unit: m/s²) of the load equipment 1, and the operation mode determination unit 36 may switch the operation mode of the leakage current sensor 10 by comparing the displacement amount (or the acceleration) of the load equipment 1 with a threshold value Th. Incidentally, when evaluating the detection signal outputted from the leakage current sensor 10 as an electric signal, the operation mode determination unit 36 may compare a voltage value as ½ or ⅓ of rated voltage of the leakage current sensor 10 with a threshold value Th.

In the case where the condition detection sensor 20 is an abnormal noise sensor, a signal corresponding to abnormal noise that occurs in the load equipment 1 is provided to the operation mode determination unit 36. The operation mode determination unit 36 obtains a frequency spectrum by performing frequency analysis on the signal outputted from the abnormal noise sensor, for example. For example, when an amplitude value of the frequency spectrum at a particular frequency is greater than or equal to a threshold value Th, the operation mode determination unit 36 determines that the switching condition is satisfied and switches the operation mode of the leakage current sensor 10 to the “abnormality diagnosis mode”. Incidentally, it is also possible for the operation mode determination unit 36 to switch the operation mode of the leakage current sensor 10 based on a particular frequency band or a plurality of frequencies.

In contrast, when the amplitude of the signal corresponding to vibration or sound that occurs in the load equipment 1 is less than the predetermined threshold value Th (i.e., when the judgment is No in the step ST6), the operation mode determination unit 36 determines that the switching condition is not satisfied and the process advances to step ST8. In this case, the operation mode determination unit 36 maintains the operation mode of the leakage current sensor 10 in the normal monitoring mode.

In the step ST6, the leakage current sensor drive unit 31 switches the operation mode of the leakage current sensor 10 from the “normal monitoring mode” to the “abnormality diagnosis mode”.

In step ST7, the operation mode determination unit 36 changes the measurement dynamic range of the leakage current sensor 10 to the aforementioned second dynamic range.

In the step ST8, the leakage current sensor 10 detects the current value of electric current leaking out from the electric cables 3a-3c.

In step ST9, the first signal processing unit 33 performs signal processing (e.g., conversion to a digital signal or the like) on the detection signal in a waveform corresponding to the electric current leaking out from the electric cables 3a-3c provided from the leakage current sensor 10.

In step ST10, the abnormality judgment unit 37 determines the presence or absence of occurrence of abnormality in the load equipment 1 based on the detection signal of the leakage current sensor 10 provided from the first signal processing unit 33 and the equipment condition signal provided from the second signal processing unit 35.

The abnormality judgment unit 37 makes the judgment on the presence or absence of occurrence of abnormality in the load equipment 1 (hereinafter referred to also as an “abnormality judgment”) based on time-series data outputted from each of the leakage current sensor 10 and the condition detection sensor 20. In the first embodiment, the abnormality judgment unit 37 determines the presence or absence of occurrence of abnormality in the load equipment 1 by comparing the amplitude value of a signal waveform as the time-series data outputted from each sensor with a threshold value. Specifically, the abnormality judgment unit 37 determines that abnormality has occurred in the load equipment 1 when both of the amplitude value of the signal waveform outputted from the leakage current sensor 10 and the amplitude value of the signal waveform outputted from the condition detection sensor 20 are over the threshold value.

It is also possible for the abnormality judgment unit 37 to determine the presence or absence of occurrence of abnormality in the load equipment 1 by comparing S/N ratios of the signals outputted from the leakage current sensor 10 and the condition detection sensor 20. For example, when making the abnormality judgment based on the detection signal outputted from the leakage current sensor 10 is easier than making the abnormality judgment based on the equipment condition signal outputted from the condition detection sensor 20, the abnormality judgment unit 37 may make the abnormality judgment by assigning priority order to the detection results of the leakage current sensor 10 and the condition detection sensor 20, such as assigning weights to the detection results. Incidentally, when the abnormality judgment unit 37 makes the abnormality judgment based on the aforementioned time-series data, the abnormality judgment unit 37 may either perform a frequency analysis process on the time-series data or perform a process of analyzing whether or not the time-series data contains a signal indicating a feature value.

Then, the abnormality judgment unit 37 generates time-series data of the leak current based on the detection signal of the leakage current sensor 10 provided from the first signal collection unit 32 and the sensor drive signal provided from the leakage current sensor drive unit 31 (e.g., the current value of the excitation current). The abnormality judgment unit 37 determines the presence or absence of occurrence of abnormality in the load equipment 1 based on two types of time-series data, namely, the time-series data of the leak current and the time-series data of the condition detection signal provided from the second signal processing unit 35. Here, the “time series” means a series in which values obtained by periodically taking measurement according to passage of time are organized or arranged.

In step ST11, the display unit 40 displays the judgment result of the abnormality judgment unit 37.

### Effect of First Embodiment

According to the first embodiment described above, the equipment diagnosis device 100 includes the leakage current sensor 10 and the condition detection sensor 20 that acquires the condition of the load equipment 1. Further, when the condition of the load equipment 1 satisfies the switching condition when the leakage current sensor 10 is operating in the normal monitoring mode, the operation mode determination unit 36 of the equipment diagnosis device 100 switches the operation mode of the leakage current sensor 10 to the operation mode for abnormality diagnosis. Accordingly, the diagnosis on the load equipment 1 can be made with ease since it is unnecessary to frequently change the detection sensitivity of the leakage current sensor 10 in a normal operation condition of the load equipment 1. In other words, the monitoring of the presence or absence of the leakage in the load equipment 1 in normal times and the abnormality diagnosis regarding the load equipment 1 can be carried out by adjusting the measurement dynamic range of one leakage current sensor 10. Accordingly, the equipment diagnosis device 100 does not need to include a plurality of leakage current sensors 10 differing in the detection sensitivity, and thus a low-cost equipment diagnosis device 100 can be provided.

Further, according to the first embodiment, the equipment diagnosis device 100 makes the diagnosis on the load equipment 1 based on the detection signal outputted from the leakage current sensor 10 and the equipment condition signal outputted from the condition detection sensor 20. Accordingly, it is possible to diagnose the presence or absence of occurrence of abnormality in the load equipment 1 based on signals outputted from a plurality of types of sensors. Thus, an equipment diagnosis device 100 with high reliability can be provided. Accordingly, an equipment diagnosis device 100 realizing a low cost, easy diagnosis on the load equipment 1, and high reliability of the diagnosis can be provided.

### Modification of First Embodiment

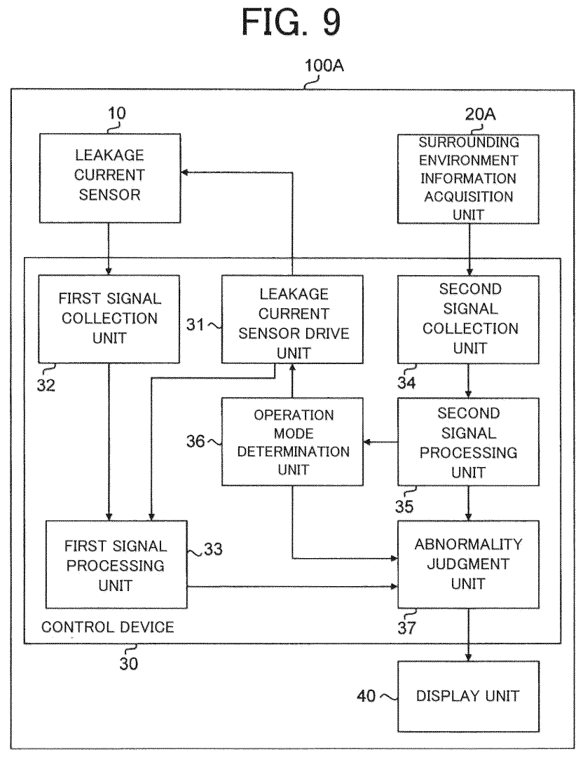

FIG. 9 is a block diagram showing the configuration of an equipment diagnosis device 100A according to a modification of the first embodiment. The equipment diagnosis device 100A according to the modification of the first embodiment differs from the equipment diagnosis device 100 according to the first embodiment in including a surrounding environment information acquisition unit 20A as the equipment condition acquisition unit instead of the condition detection sensor 20. Except for this feature, the equipment diagnosis device 100A according to the modification of the first embodiment is the same as the equipment diagnosis device 100 according to the first embodiment. Thus, FIG. 1 is referred to in the following description.

As shown in FIG. 9, the equipment diagnosis device 100A includes the leakage current sensor 10, the surrounding environment information acquisition unit 20A as the equipment condition acquisition unit, the control device 30, and the display unit 40.

The surrounding environment information acquisition unit 20A detects surrounding environment information indicating the condition of a surrounding environment of the load equipment 1 (see FIG. 1). The surrounding environment information includes, for example, at least one of weather at an installation site where the load equipment 1 is installed, rainfall at the installation site, illuminance at the installation site, wind velocity at the installation site, temperature at the installation site, or humidity at the installation site. Incidentally, the “installation site” includes the vicinity of the place where the load equipment 1 is installed.

The surrounding environment information acquisition unit 20A is, for example, a rainfall sensor that detects the rainfall at the installation site of the load equipment 1. The surrounding environment information acquisition unit 20A can also be an illuminance sensor that detects the illuminance at the installation site of the load equipment 1, or a wind velocity sensor that detects the wind velocity at the installation site. Further, the surrounding environment information acquisition unit 20A can also be a temperature sensor that detects the temperature at the installation site, a humidity sensor that detects the humidity at the installation site, or the like. Furthermore, the surrounding environment information acquisition unit 20A may acquire weather information indicating the weather at the installation site of the load equipment 1 by accessing a server of a meteorological information provision service, for example. The surrounding environment information acquisition unit 20A inputs a surrounding environment signal, as a condition signal indicating the surrounding environment of the load equipment 1, to the second signal collection unit 34. Incidentally, the surrounding environment information acquisition unit 20A may be arranged in any method as long as the surrounding environment of the load equipment 1 can be detected directly or indirectly.

Although the surrounding environment of the load equipment 1 does not vary in conjunction with the operation condition of the load equipment 1, the surrounding environment can influence the operation of the load equipment 1 as an external factor. In the modification of the first embodiment, when the surrounding environment of the load equipment 1 satisfies a predetermined switching condition when the leakage current sensor 10 is operating in the normal monitoring mode, the operation mode determination unit 36 of the control device 30 switches the operation mode of the leakage current sensor 10 to the operation mode for abnormality diagnosis. In other words, when the surrounding environment of the load equipment 1 satisfies the switching condition, the operation mode determination unit 36 switches the measurement dynamic range of the leakage current sensor 10 to the aforementioned second dynamic range with high detection sensitivity. Incidentally, when the surrounding environment of the load equipment 1 satisfies the operation mode switching condition, the operation mode determination unit 36 can also switch the measurement dynamic range of the leakage current sensor 10 to a dynamic range with a wide frequency range. Further, when the surrounding environment of the load equipment 1 satisfies the operation mode switching condition, the operation mode determination unit 36 can also switch the measurement dynamic range of the leakage current sensor 10 to a dynamic range with high detection sensitivity and a wide frequency range.

The abnormality judgment unit 37 makes the abnormality judgment in regard to the load equipment 1 based on time-series data outputted from each of the leakage current sensor 10 and the surrounding environment information acquisition unit 20A. Specifically, the abnormality judgment unit 37 determines that abnormality has occurred in the load equipment 1 when the amplitude value of the signal waveform outputted from the leakage current sensor 10 is over the threshold value and the surrounding environment information outputted from the surrounding environment information acquisition unit 20A satisfies a predetermined condition.

### Effect of Modification of First Embodiment

According to the modification of the first embodiment described above, the equipment diagnosis device 100A includes the leakage current sensor 10, the surrounding environment information acquisition unit 20A that acquires the surrounding environment of the load equipment 1, and the operation mode determination unit 36. When the surrounding environment of the load equipment 1 satisfies the switching condition, the operation mode determination unit 36 switches the operation mode of the leakage current sensor 10 to the operation mode for abnormality diagnosis. Accordingly, the diagnosis on the load equipment 1 can be made with ease since it is unnecessary to frequently change the detection sensitivity of the leakage current sensor 10 in a normal operation condition of the load equipment 1. In other words, the monitoring of the presence or absence of the leakage in the load equipment 1 in normal times and the abnormality diagnosis regarding the load equipment 1 can be carried out by adjusting the measurement dynamic range of one leakage current sensor 10. Accordingly, the equipment diagnosis device 100A does not need to include a plurality of leakage current sensors 10 differing in the detection sensitivity, and thus a low-cost equipment diagnosis device 100A can be provided.

Further, according to the modification of the first embodiment, the equipment diagnosis device 100A makes the diagnosis on the load equipment 1 based on the detection signal outputted from the leakage current sensor 10 and the surrounding environment signal outputted from the surrounding environment information acquisition unit 20A. Accordingly, it is possible to diagnose the presence or absence of occurrence of abnormality in the load equipment 1 based on signals outputted from a plurality of types of sensors. Thus, an equipment diagnosis device 100A with high reliability can be provided. Accordingly, an equipment diagnosis device 100A realizing a low cost, easy diagnosis on the load equipment 1, and high reliability of the diagnosis can be provided.

### Second Embodiment

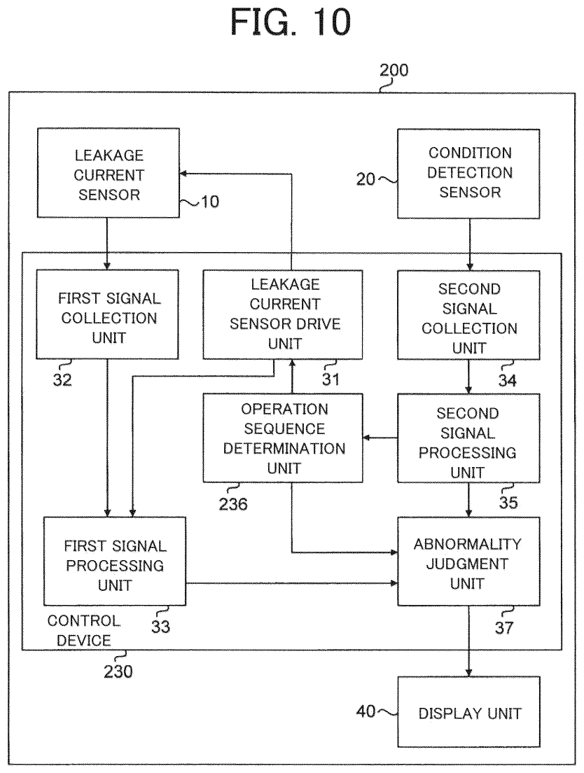

FIG. 10 is a block diagram showing the configuration of an equipment diagnosis device 200 according to a second embodiment. In FIG. 10, each component identical or corresponding to a component shown in FIG. 1 or FIG. 6 is assigned the same reference character as in FIG. 1 or FIG. 6. The equipment diagnosis device 200 according to the second embodiment differs from the equipment diagnosis device 100 according to the first embodiment in that the operation mode determination unit is an operation sequence determination unit 236 that determines an operation sequence indicating the order of operation modes. Except for this feature, the equipment diagnosis device 200 according to the second embodiment is the same as the equipment diagnosis device 100 according to the first embodiment. Thus, FIG. 1 is referred to in the following description.

As shown in FIG. 10, the equipment diagnosis device 200 includes the leakage current sensor 10, the condition detection sensor 20, a control device 230 and the display unit 40.

The control device 230 includes the leakage current sensor drive unit 31, the first signal collection unit 32, the first signal processing unit 33, the second signal collection unit 34, the second signal processing unit 35, the operation sequence determination unit 236 and the abnormality judgment unit 37.

The operation sequence determination unit 236 determines the operation sequence of the leakage current sensor 10 based on the equipment condition signal indicating the condition of the load equipment 1 (see FIG. 1) provided from the condition detection sensor 20 via the second signal processing unit 35.

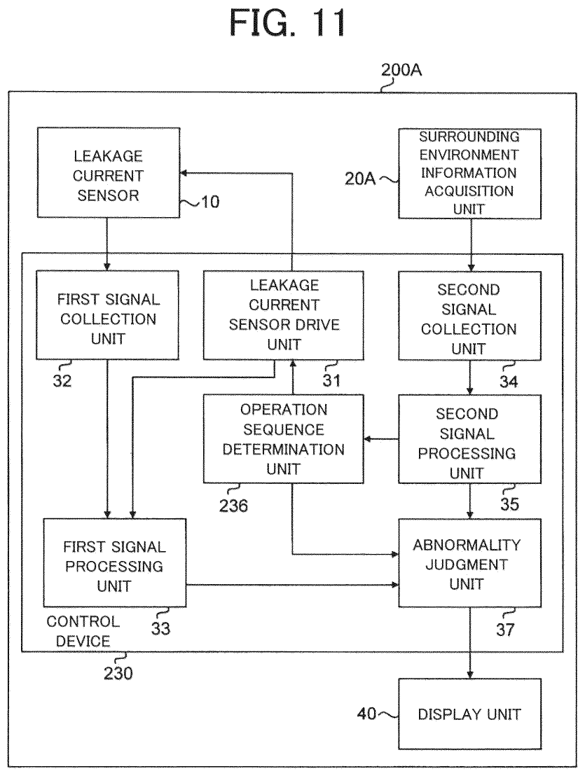

FIG. 11 is a block diagram showing another example of the configuration of an equipment diagnosis device 200A according to the second embodiment. As shown in FIG. 11, the equipment diagnosis device 200A may include the aforementioned surrounding environment information acquisition unit 20A shown in FIG. 9 instead of the condition detection sensor 20. In this case, the operation sequence determination unit 236 may determine the operation sequence of the leakage current sensor 10 based on the surrounding environment information provided from the surrounding environment information acquisition unit 20A.

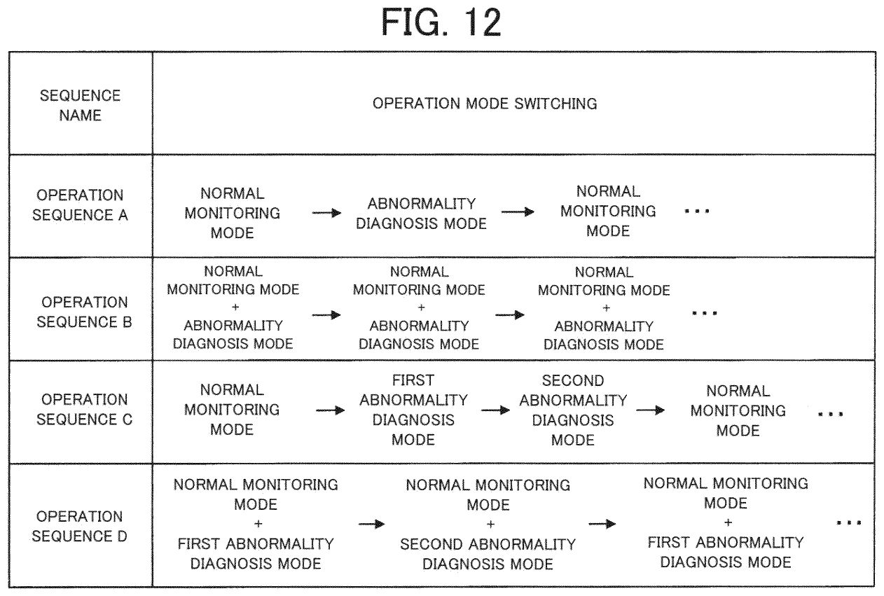

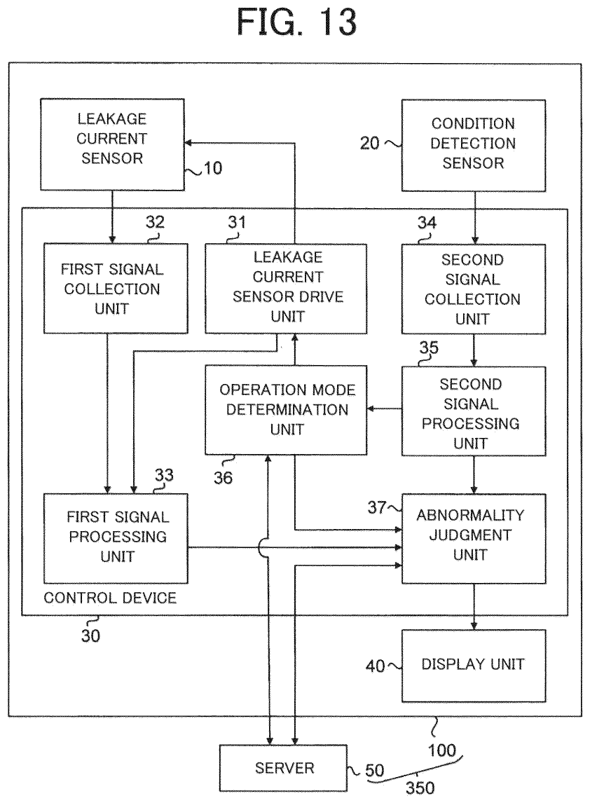

FIG. 12 is a diagram showing an example of operation sequences A-D of the leakage current sensor 10 of the equipment diagnosis device 200 according to the second embodiment. The “operation sequence A” shown in FIG. 12 is a sequence of alternately executing the normal monitoring mode and the abnormality diagnosis mode as two operation modes. Specifically, in the operation sequence A, when the condition of the load equipment 1 (or the surrounding environment of the load equipment 1) satisfies the operation mode switching condition, the switching from the normal monitoring mode to the abnormality monitoring mode is performed. Then, when the condition of the load equipment 1 (or the surrounding environment of the load equipment 1) stops satisfying the operation mode switching condition, the switching from the abnormality monitoring mode to the normal monitoring mode is performed.

The “operation sequence B” is a sequence of repeatedly executing a “normal monitoring mode+abnormality diagnosis mode”. The “normal monitoring mode+abnormality diagnosis mode” is a mode of simultaneously executing the normal monitoring mode and the abnormality diagnosis mode.

The “operation sequence C” is a sequence of operating the leakage current sensor 10 in the order of the “normal monitoring mode”, a “first abnormality diagnosis mode” and a “second abnormality diagnosis mode” as three operation modes. The “first abnormality diagnosis mode” is an abnormality diagnosis mode in which the leakage current sensor 10 is operated in a first measurement dynamic range. The “second abnormality diagnosis mode” is an abnormality diagnosis mode in which the leakage current sensor 10 is operated in a second measurement dynamic range.

When the condition of the load equipment 1 satisfies a switching condition, the operation sequence determination unit 236 successively performs switching from the normal monitoring mode to the first abnormality diagnosis mode, switching from the first abnormality diagnosis mode to the second abnormality diagnosis mode, and switching from the second abnormality diagnosis mode to the normal monitoring mode. As above, in the operation sequence C, the leakage current sensor 10 operates in two abnormality diagnosis modes differing in the measurement dynamic range and thereby detects the presence or absence of the leakage in the electric cables 3a-3c (see FIG. 2). This facilitates analysis of correlation between the equipment condition signal (or the surrounding environment information) and the detection signal outputted from the leakage current sensor 10. Further, for the judgment on the presence or absence of abnormality in the load equipment 1, the amount of information in the detection signal outputted from the leakage current sensor 10 increases, and thus the reliability of the equipment diagnosis device 200, 200A can be increased.

The “operation sequence D” is a sequence of alternately executing a “normal monitoring mode+first abnormality diagnosis mode” and a “normal monitoring mode+second abnormality diagnosis mode” as two operation modes. The “normal monitoring mode+first abnormality diagnosis mode” is a mode of simultaneously executing the normal monitoring mode and the aforementioned first abnormality diagnosis mode. The “normal monitoring mode+second abnormality diagnosis mode” is a mode of simultaneously executing the normal monitoring mode and the aforementioned second abnormality diagnosis mode. Incidentally, the number of types of operation modes constituting each operation sequence of the leakage current sensor 10 can also be greater than three types. As above, in the second embodiment, two operation modes or three or more operation modes constitute one set and the leakage current sensor 10 operates accordingly.

### Effect of Second Embodiment

According to the second embodiment described above, the operation sequence determination unit 236 of the equipment diagnosis device 200 determines the operation sequence of the leakage current sensor 10 based on the detection result of the condition detection sensor 20 and the environment information indicating the use environment of the load equipment 1. By this, a plurality of diagnosis modes can be executed, by which the amount of information in regard to the judgment on the abnormality diagnosis on the load equipment 1 can be increased. Accordingly, the reliability of the equipment diagnosis device 200, 200A can be increased.

### Third Embodiment

FIG. 13 is a block diagram showing the configuration of an equipment diagnosis system 350 according to a third embodiment. In FIG. 13, each component identical or corresponding to a component shown in FIG. 1 or FIG. 6 is assigned the same reference character as in FIG. 1 or FIG. 6. The third embodiment differs from the second embodiment in that a server 50 communicating with the equipment diagnosis device 100 operates in cooperation with the abnormality judgment unit 37 and the operation mode determination unit 36. Except for this feature, the third embodiment is the same as the first embodiment.

As shown in FIG. 13, the equipment diagnosis system 350 includes the equipment diagnosis device 100 and the server 50 as an external server. The server 50 communicates with the equipment diagnosis device 100 via a network. The server 50 is a cloud server, for example.

The server 50 in cooperation with (in collaboration with) the abnormality judgment unit 37 makes the diagnosis on the load equipment 1. Further, the server 50 in cooperation with (in collaboration with) the operation mode determination unit 36 determines the operation mode of the leakage current sensor 10. Accordingly, the switching condition by the operation mode determination unit 36 can be updated based on the judgment result of the abnormality judgment unit 37. Further, compared to a configuration without the server 50 (stand-alone configuration), the provision of the server 50, to which information in various fields is inputted, increases the amount of information used for making the diagnosis on the load equipment 1 (see FIG. 1), by which the reliability of the diagnosis on the load equipment 1 can be increased. Furthermore, the server 50 can analyze the correlation between the condition detection sensor 20 and the leakage current sensor 10 by making use of artificial intelligence or the like and thereby increase the reliability of the diagnosis on the load equipment 1.

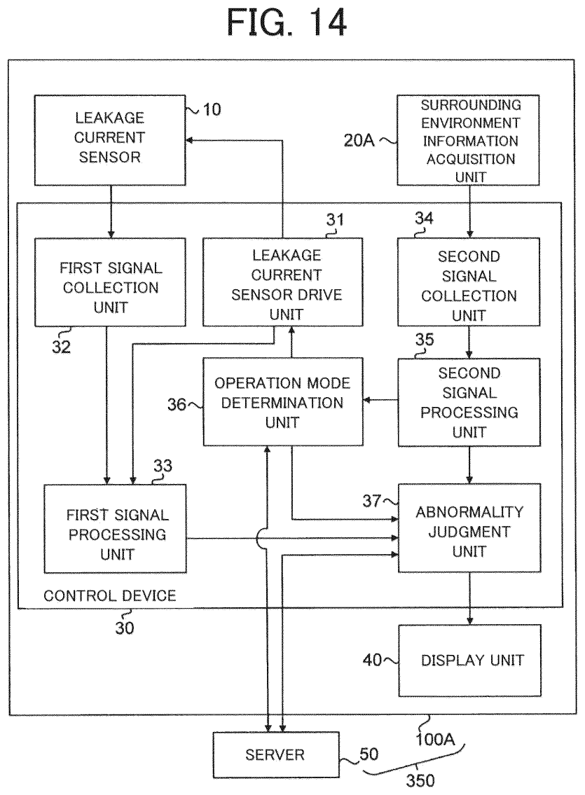

FIG. 14 is a block diagram showing another example of the configuration of the equipment diagnosis system 350 according to the third embodiment. As shown in FIG. 14, the equipment diagnosis system 350 may also be formed with the equipment diagnosis device 100A according to the modification of the first embodiment and the server 50. In this case, the server 50 may analyze the correlation between the surrounding environment information acquisition unit 20A and the leakage current sensor 10 by making use of artificial intelligence or the like.

### Effect of Third Embodiment

According to the third embodiment described above, the equipment diagnosis system 350 includes the equipment diagnosis device 100 and the server 50 communicating with the equipment diagnosis device 100, 100A via the network, and the server 50 in cooperation with the abnormality judgment unit 37 makes the diagnosis on the load equipment 1. Thus, the reliability of the diagnosis on the load equipment 1 can be increased. Accordingly, an equipment diagnosis system 350 realizing a low cost, easy diagnosis on the load equipment 1, and high reliability of the diagnosis can be provided.

Further, according to the third embodiment, the server 50 in cooperation with the operation mode determination unit 36 determines the operation mode of the leakage current sensor 10.

Accordingly, the operation mode switching condition by the operation mode determination unit 36 can be updated based on the judgment result of the abnormality judgment unit 37.

### Modification of Third Embodiment

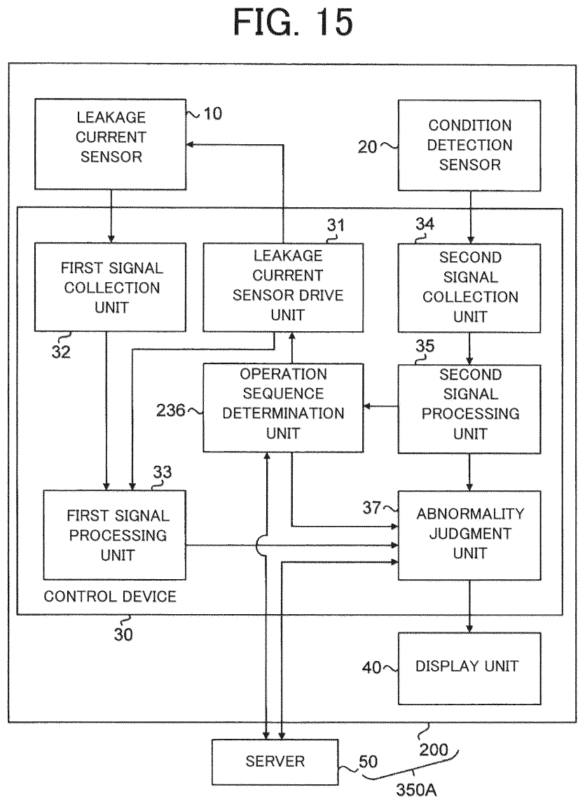

FIG. 15 is a block diagram showing the configuration of an equipment diagnosis system 350A according to a modification of the third embodiment. In FIG. 15, each component identical or corresponding to a component shown in FIG. 10 is assigned the same reference character as in FIG. 10. The equipment diagnosis system 350A according to the modification of the third embodiment differs from the equipment diagnosis system 350 according to the third embodiment in that the equipment diagnosis system 350A is formed with the equipment diagnosis device 200 according to the second embodiment and the server 50. Except for this feature, the equipment diagnosis system 350A according to the modification of the third embodiment is the same as the equipment diagnosis system 350 according to the third embodiment.

As shown in FIG. 15, the equipment diagnosis system 350A includes the equipment diagnosis device 200 and the server 50. The server 50 communicates with the equipment diagnosis device 200 via the network. The server 50 in cooperation with (in collaboration with) the operation sequence determination unit 236 determines the operation sequence of the leakage current sensor 10. Accordingly, the operation sequence switching condition by the operation sequence determination unit 236 can be updated based on the judgment result of the abnormality judgment unit 37.

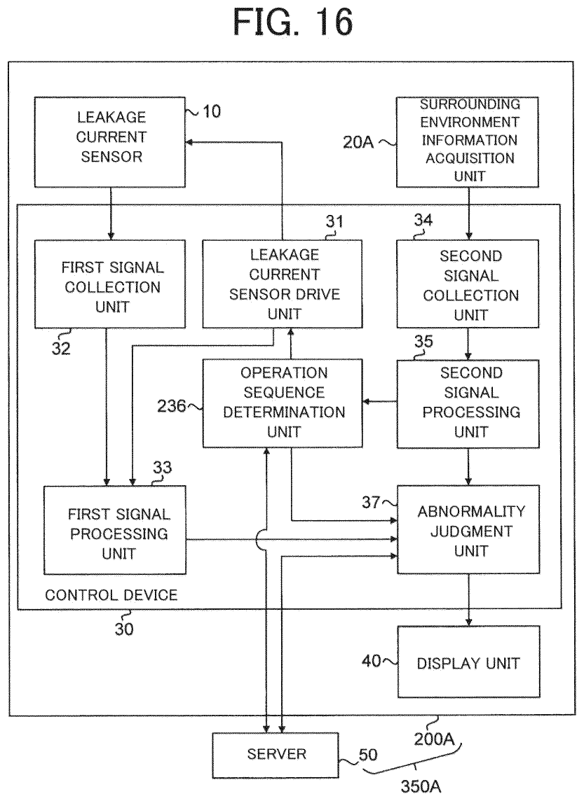

FIG. 16 is a block diagram showing another example of the configuration of the equipment diagnosis system 350A according to the modification of the third embodiment. As shown in FIG. 16, the equipment diagnosis system 350A may also be formed with the aforementioned equipment diagnosis device 200A shown in FIG. 11 and the server 50.

### Effect of Modification of Third Embodiment

According to the modification of the third embodiment described above, the server 50 in cooperation with the operation sequence determination unit 236 determines the operation sequence of the leakage current sensor 10. Accordingly, the operation sequence switching condition by the operation sequence determination unit 236 can be updated based on the judgment result of the abnormality judgment unit 37.

### Fourth Embodiment

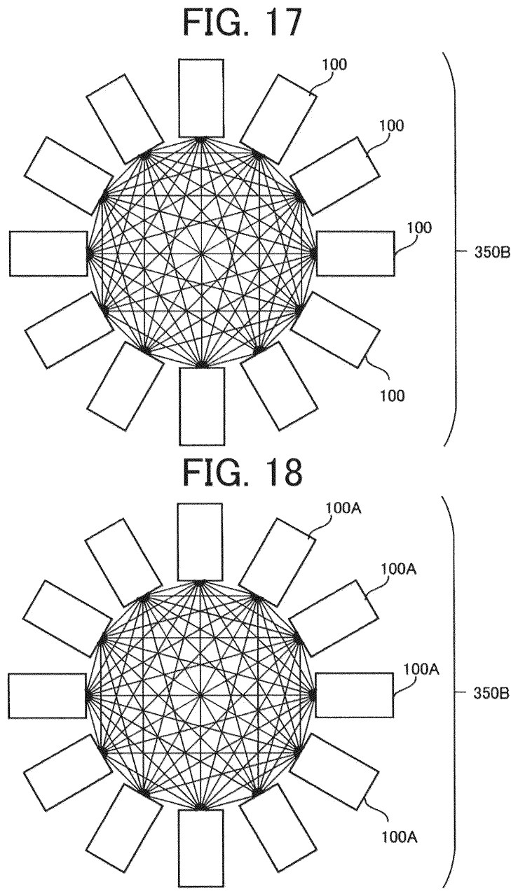

FIG. 17 is a block diagram showing the configuration of an equipment diagnosis system 350B according to a fourth embodiment. FIG. 17 includes components identical or corresponding to components shown in FIG. 1 or FIG. 6, and such components are assigned the same reference characters as in FIG. 1 or FIG. 6. The fourth embodiment differs from the first or third embodiment in that a plurality of equipment diagnosis devices 100 constitute a network with each other and the plurality of equipment diagnosis devices 100 in cooperation with each other via the network determine the operation of the abnormality judgment unit 37 and the operation mode determination unit 36. Except for this feature, the fourth embodiment is the same as the first or third embodiment. The plurality of equipment diagnosis devices 100 form an equipment diagnosis device 100 and a group of other equipment diagnosis devices that communicate with the equipment diagnosis device 100 via the network.

As shown in FIG. 17, the equipment diagnosis system 350B includes a plurality of equipment diagnosis devices 100. The plurality of equipment diagnosis devices 100 communicate with each equipment diagnosis device 100 via the network. The network is, for example, a wireless network such as a mesh network.

Each equipment diagnosis device 100 on the network makes the diagnosis on the load equipment 1 by operating in cooperation with (in collaboration with) the abnormality judgment unit 37 of a particular equipment diagnosis device 100. Further, similarly, each equipment diagnosis device 100 on the network determines the operation mode of the leakage current sensor 10 by operating in cooperation with (in collaboration with) the operation mode determination unit 36 of the particular equipment diagnosis device. Accordingly, the switching condition by the operation mode determination unit 36 can be updated based on the judgment result of the abnormality judgment unit 37. Further, compared to a configuration with no network (stand-alone configuration), making use of information in the equipment diagnosis devices 100, to which information in various fields is inputted, increases the amount of information used for making the diagnosis on the load equipment 1 (see FIG. 1), by which the reliability of the diagnosis on the load equipment 1 can be increased. Furthermore, the reliability of the diagnosis on the load equipment 1 can be increased by analyzing the correlation between the condition detection sensor 20 and the leakage current sensor 10 by making use of artificial intelligence or the like by means of distributed processing by the equipment diagnosis devices 100 on the network. Incidentally, after the diagnosis/analysis by the particular equipment diagnosis device 100 is finished, the diagnosis/analysis is executed successively by designating one of the plurality of equipment diagnosis devices 100 on the network as the particular equipment diagnosis device 100.

FIG. 18 is a block diagram showing another example of the configuration of the equipment diagnosis system 350B according to the fourth embodiment. As shown in FIG. 18, the equipment diagnosis system 350 may also be formed with the equipment diagnosis devices 100A (shown in FIG. 9 and FIG. 14) according to the modification of the first embodiment. In this case, the correlation between the surrounding environment information acquisition unit 20A and the leakage current sensor 10 may be analyzed by making use of artificial intelligence or the like by means of distributed processing by the equipment diagnosis devices 100A on the network.

### Effect of Fourth Embodiment

According to the fourth embodiment described above, in the equipment diagnosis system 350B, a plurality of equipment diagnosis devices 100, 100A execute communication via the network and make the diagnosis on the load equipment 1 by operating in cooperation with the abnormality judgment unit 37 of a particular equipment diagnosis device 100, 100A. By this, the reliability of the diagnosis on the load equipment 1 can be increased and a server-less configuration can be implemented. Accordingly, an equipment diagnosis system 350B realizing a low cost, elimination of system failure caused by a single failure of a server or the like, easy diagnosis on the load equipment 1, and high reliability of the diagnosis can be provided.

Further, according to the fourth embodiment, a plurality of equipment diagnosis devices 100, 100A determine the operation mode of the leakage current sensor 10 by operating in cooperation with the operation mode determination unit 36 of the particular equipment diagnosis device 100, 100A. Accordingly, the operation mode switching condition by the operation mode determination unit 36 can be updated based on the judgment result of the abnormality judgment unit 37.

### Modification of Fourth Embodiment

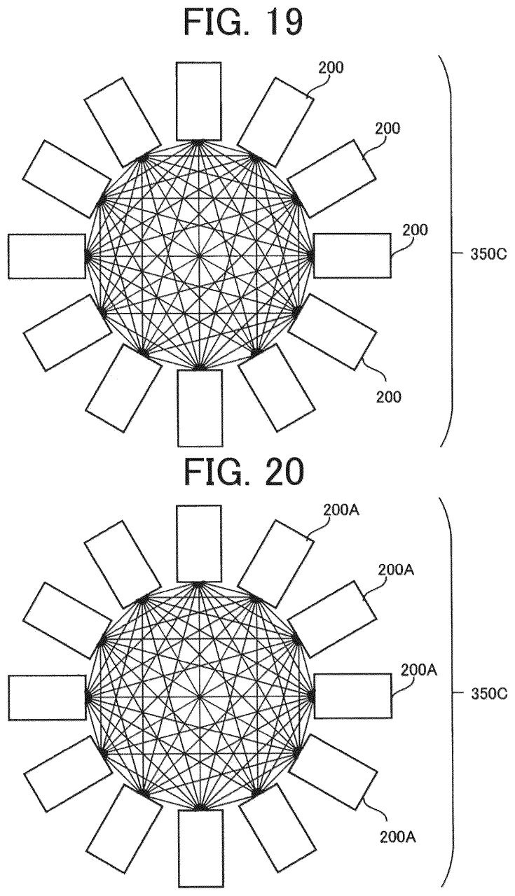

FIG. 19 is a block diagram showing the configuration of an equipment diagnosis system 350C according to a modification of the fourth embodiment. FIG. 19 includes components identical or corresponding to components shown in FIG. 10, and such components are assigned the same reference characters as in FIG. 10. The equipment diagnosis system 350C according to the modification of the fourth embodiment differs from the equipment diagnosis system 350B according to the fourth embodiment in that the equipment diagnosis system 350C is formed with a plurality of equipment diagnosis devices 200 according to the second embodiment. Except for this feature, the equipment diagnosis system 350C according to the modification of the fourth embodiment is the same as the equipment diagnosis system 350B according to the fourth embodiment.

As shown in FIG. 19, the equipment diagnosis system 350C includes a plurality of equipment diagnosis devices 200. The plurality of equipment diagnosis devices 200 communicate with each equipment diagnosis device 200 via the network. Each equipment diagnosis device 200 on the network determines the operation sequence of the leakage current sensor 10 by operating in cooperation with (in collaboration with) the operation sequence determination unit 236 of a particular equipment diagnosis device 200. Accordingly, the operation sequence switching condition by the operation sequence determination unit 236 can be updated based on the judgment result of the abnormality judgment unit 37.

FIG. 20 is a block diagram showing another example of the configuration of the equipment diagnosis system 350C according to the modification of the fourth embodiment. As shown in FIG. 20, the equipment diagnosis system 350C may also be formed with the aforementioned equipment diagnosis devices 200A (shown in FIG. 11 and FIG. 16) shown in FIG. 11.

### Effect of Modification of Fourth Embodiment

According to the modification of the fourth embodiment described above, a plurality of equipment diagnosis devices 200, 200A execute communication via the network and determine the operation sequence of the leakage current sensor 10 by operating in cooperation with the operation sequence determination unit 236 of a particular equipment diagnosis device 200, 200A. Accordingly, the operation sequence switching condition by the operation sequence determination unit 236 can be updated based on the judgment result of the abnormality judgment unit 37.

### DESCRIPTION OF REFERENCE CHARACTERS

1: load equipment, 2: power supply unit, 3a, 3b, 3c: electric cable, 9: ground, 10: leakage current sensor, 11: magnetic core, 11a: hollow part, 12: excitation coil, 13: detection coil, 20: condition detection sensor, 20A: surrounding environment information acquisition unit, 30, 30A, 230: control device, 31: leakage current sensor drive unit, 32: first signal collection unit, 33: first signal processing unit, 34: second signal collection unit, 35: second signal processing unit, 36: operation mode determination unit, 37: abnormality judgment unit, 50: server, 100, 100A, 200, 200A: equipment diagnosis device, 236: operation sequence determination unit, 350, 350A, 350B, 350C: equipment diagnosis system

1: An equipment diagnosis device to make a diagnosis on load equipment driven by electric power supplied from a power supply through an electric circuit, the equipment diagnosis device comprising:
a leakage current sensor to output a detection signal in a waveform corresponding to electric current leaking out from the electric circuit;
equipment condition acquisition circuitry to acquire equipment condition as at least either condition of the load equipment or surrounding environment of the load equipment;
operation mode determination circuitry to determine an operation mode of the leakage current sensor at an operation mode for leakage detection in normal times or an operation mode for abnormality diagnosis based on a condition signal outputted from the equipment condition acquisition circuitry;
leakage current sensor drive circuitry to make the leakage current sensor operate in the operation mode determined by the operation mode determination circuitry; and
diagnosis circuitry to make the diagnosis based on the detection signal outputted from the leakage current sensor and the condition signal outputted from the equipment condition acquisition circuitry,
wherein when the equipment condition satisfies a predetermined switching condition while the leakage current sensor is operating in the operation mode for leakage detection in normal times, the operation mode determination circuitry switches the operation mode of the leakage current sensor to the operation mode for abnormality diagnosis, and
current detection sensitivity when the leakage current sensor operates in the operation mode for abnormality diagnosis is higher than current detection sensitivity when the leakage current sensor operates in the operation mode for leakage detection in normal times.

2. (canceled)

3: The equipment diagnosis device according to claim 1, wherein a frequency range when the leakage current sensor operates in the operation mode for abnormality diagnosis is wider than a frequency range when the leakage current sensor operates in the operation mode for leakage detection in normal times.

4: The equipment diagnosis device according to claim 1, wherein
the equipment condition acquisition circuitry outputs a signal as the condition signal, the signal corresponding to vibration or sound that occurs in the load equipment, and
when amplitude of the signal is greater than or equal to a predetermined threshold value, the operation mode determination circuitry determines that the switching condition is satisfied and switches the operation mode of the leakage current sensor to the operation mode for abnormality diagnosis.

5: The equipment diagnosis device according to claim 4, wherein when the amplitude of the signal is less than the threshold value, the operation mode determination circuitry determines that the switching condition is not satisfied and maintains the operation mode of the leakage current sensor in the operation mode for leakage detection in normal times.

6: The equipment diagnosis device according to claim 1, wherein the equipment condition acquisition circuitry includes at least one of a vibration sensor to measure vibration of the load equipment, a temperature sensor or infrared sensor to measure temperature of the load equipment, a motion sensor to detect motion of the load equipment, an abnormal noise sensor to detect abnormal noise when the load equipment is in operation, an electromagnetic wave sensor to detect presence or absence of electric discharge in the load equipment, a water leakage current sensor to detect presence or absence of water leakage in the load equipment, an oil leakage current sensor to detect presence or absence of oil leakage in the load equipment, or a smoking sensor to detect presence or absence of smoking in the load equipment.

7: The equipment diagnosis device according to claim 1, wherein the equipment condition acquisition circuitry is a noise meter to measure electrical noise or electromagnetic noise of the load equipment.

8: The equipment diagnosis device according to claim 1, wherein the surrounding environment of the load equipment acquired by the equipment condition acquisition circuitry includes at least one of weather at an installation site where the load equipment is installed, rainfall at the installation site, illuminance at the installation site, wind velocity at the installation site, temperature at the installation site, or humidity at the installation site.

9: The equipment diagnosis device according to claim 1, wherein
the operation mode for abnormality diagnosis includes a first abnormality diagnosis mode of operating with a first measurement dynamic range and a second abnormality diagnosis mode of operating with a second measurement dynamic range, and
when the switching condition is satisfied, the operation mode determination circuitry successively performs switching from the operation mode for leakage detection in normal times to the first abnormality diagnosis mode, switching from the first abnormality diagnosis mode to the second abnormality diagnosis mode, and switching from the second abnormality diagnosis mode to the operation mode for leakage detection in normal times.

10: The equipment diagnosis device according to claim 1, wherein the leakage current sensor includes:
a core part;
a first coil that is wound around the core part and conducts excitation current as drive current applied from the leakage current sensor drive circuitry; and
a second coil that is wound around the core part and outputs a signal, which represents induced electromotive force, as the detection signal, the induced electromotive force occurring due to the excitation current.

11: The equipment diagnosis device according to claim 10, wherein the leakage current sensor drive circuitry makes the leakage current sensor operate in the operation mode determined by the operation mode determination circuitry by controlling at least one of a current value of the excitation current, a frequency of the excitation current, or a waveform of the excitation current.

12: The equipment diagnosis device according to claim 1, further comprising a notification unit to notify of result of the diagnosis by the diagnosis circuitry.

13: An equipment diagnosis system comprising:
the equipment diagnosis device according to claim 1; and
a server to communicate with the equipment diagnosis device via a network,
wherein the server makes the diagnosis on the load equipment by operating in cooperation with the diagnosis circuitry.

14: The equipment diagnosis system according to claim 13, wherein the server determines the operation mode of the leakage current sensor by operating in cooperation with the operation mode determination circuitry.

15: An equipment diagnosis system comprising:
the equipment diagnosis device according to claim 1; and
a group of other equipment diagnosis devices to communicate with the equipment diagnosis device via a network,
wherein the group of other equipment diagnosis devices makes the diagnosis on the load equipment by making their diagnosis circuitry operate in cooperation with each other.

16: The equipment diagnosis system according to claim 15, wherein the equipment diagnosis devices determine the operation mode of the leakage current sensor by operating in cooperation with the operation mode determination circuitry.
